(19) United States
(12) Patent Application Publication
(10) Pub. No.: US 2018/0267087 A1
(43) Pub. Date: Sep. 20, 2018

(54) MICROWAVE SENSOR AND MICROWAVE IMAGING DEVICE

(71) Applicant: KABUSHIKI KAISHA TOSHIBA, Tokyo (JP)

(72) Inventors: Tazumi NAGASAWA, Yokohama (JP); Hirofumi SUTO, Kawasaki (JP); Michinaga YAMAGISHI, Zama (JP); Taro KANAO, Kawasaki (JP); Kiwamu KUDO, Kamakura (JP); Koichi MIZUSHIMA, Kamakura (JP)

(73) Assignee: KABUSHIKI KAISHA TOSHIBA, Tokyo (JP)

(21) Appl. No.: 15/706,140

(22) Filed: Sep. 15, 2017

(30) Foreign Application Priority Data
Mar. 17, 2017 (JP) 2017-053460
Aug. 29, 2017 (JP) 2017-164376

(51) Int. Cl. G01R 27/04; H01F 10/14; H01F 10/16; H01F 10/32

(52) U.S. Cl. CPC G01R 27/04; H01F 10/3286; H01F 10/16; H01F 10/14

(57) ABSTRACT

According to one embodiment, a microwave sensor includes a first stacked body and a first controller. The first stacked body includes a first magnetic layer, a second magnetic layer, and a first nonmagnetic layer. The first nonmagnetic layer is provided between the first magnetic layer and the second magnetic layer. The first controller is electrically connected to the first magnetic layer and the second magnetic layer. The first controller is configured to supply a current to the first stacked body and is configured to sense a value corresponding to a first electrical resistance between the first magnetic layer and the second magnetic layer. A second magnetization of the second magnetic layer is aligned with a first direction from the first magnetic layer toward the second magnetic layer. The value corresponding to the first electrical resistance changes according to a microwave.

### CROSS-REFERENCE TO RELATED APPLICATIONS

This application is based upon and claims the benefit of priority from Japanese Patent Application No.2017-053460, filed on Mar. 17, 2017, and Japanese Patent Application No. 2017-164376, filed on Aug. 29, 2017; the entire contents of which are incorporated herein by reference.

### FIELD

Embodiments described herein relate generally to a microwave sensor and a microwave imaging device.

### BACKGROUND

A microwave sensor has been proposed in which a magnetoresistance effect element is applied. It is desirable to increase the sensing sensitivity of the microwave sensor.

### BRIEF DESCRIPTION OF THE DRAWINGS

FIG. 1 shows a basic configuration of a microwave sensor according to a first embodiment;

FIG. 2 shows a basic configuration of a microwave sensor according to a second embodiment;

FIG. 3 shows a basic configuration of a microwave sensor according to a third embodiment;

FIG. 4 shows the microwave sensor according to the third embodiment further comprising a control mechanism;

FIG. 5 shows a basic configuration of a microwave sensor according to a fifth embodiment;

FIG. 6 is a schematic view of a microwave imaging device.

FIG. 7 is a schematic view illustrating a microwave sensor according to a fifth embodiment;

FIG. 8 is a schematic view illustrating a characteristic of the microwave sensor according to the fifth embodiment;

FIG. 9A and FIG. 9B are schematic cross-sectional views illustrating the microwave sensor according to the fifth embodiment;

FIG. 10A and FIG. 10B are schematic cross-sectional views illustrating another microwave sensor according to the fifth embodiment;

FIG. 11A and FIG. 11B are schematic cross-sectional views illustrating another microwave sensor according to the fifth embodiment;

FIG. 12A and FIG. 12B are schematic cross-sectional views illustrating another microwave sensor according to the fifth embodiment;

FIG. 13 is a schematic view illustrating another microwave sensor according to the fifth embodiment;

FIG. 14 is a schematic view illustrating another microwave sensor according to the fifth embodiment;

FIG. 15A to FIG. 15C are schematic cross-sectional views illustrating other microwave sensors according to the fifth embodiment;

FIG. 16A and FIG. 16B are schematic cross-sectional views illustrating other microwave sensors according to the fifth embodiment;

FIG. 17A to FIG. 17C are schematic cross-sectional views illustrating other microwave sensors according to the fifth embodiment;

FIG. 18 is a schematic view illustrating a microwave sensor according to a sixth embodiment;

FIG. 19 is a schematic view illustrating another microwave sensor according to the sixth embodiment;

FIG. 20 is a schematic view illustrating another microwave sensor according to the sixth embodiment;

FIG. 21 is a schematic view illustrating another microwave sensor according to the sixth embodiment; and

FIG. 22 is a schematic view illustrating a microwave imaging device according to a seventh embodiment.

### DETAILED DESCRIPTION

According to one embodiment, a microwave sensor includes a first stacked body and a first controller. The first stacked body includes a first magnetic layer, a second magnetic layer, and a first nonmagnetic layer. The first nonmagnetic layer is provided between the first magnetic layer and the second magnetic layer. The first controller is electrically connected to the first magnetic layer and the second magnetic layer. The first controller is configured to supply a current to the first stacked body and is configured to sense a value corresponding to a first electrical resistance between the first magnetic layer and the second magnetic layer. A second magnetization of the second magnetic layer is aligned with a first direction from the first magnetic layer toward the second magnetic layer. The value corresponding to the first electrical resistance changes according to a microwave.

Various embodiments will be described hereinafter with reference to the accompanying drawings.

The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

### FIRST EMBODIMENT

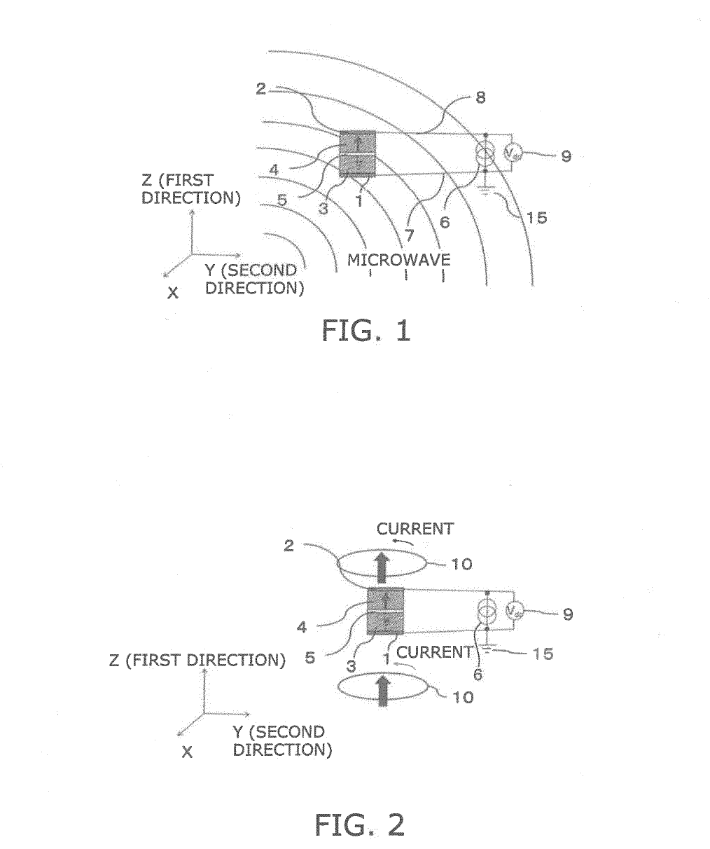

FIG. 1 is a microwave sensor according to a first embodiment.

The microwave sensor according to the embodiment senses a microwave.

The microwave sensor according to the first embodiment includes a first electrode 1 and a second electrode 2; and a first magnetic layer 3 in which the orientation of a magnetization is changeable and is oriented in a surface normal direction, a nonmagnetic layer 5, and a second magnetic layer 4 in which the orientation of a magnetization is fixed and oriented in a surface normal direction are stacked in this order between the first electrode 1 and the second electrode 2. In other words, the second magnetic layer 4 in which the orientation of the magnetization is fixed is provided between the second electrode 2 and the first magnetic layer 3. Also, the nonmagnetic layer 5 is provided between the first magnetic layer 3 and the second magnetic layer 4.

In the embodiment, a direction from the first magnetic layer 3 side (e.g., the page surface lower side) toward the second magnetic layer 4 side (e.g., the page surface upper side) is called a first direction (a +z axis direction or a −z axis direction); a direction crossing (e.g., orthogonal to) to the first direction is called a second direction (a +x axis direction, a −x axis direction, a +y axis direction, or a −y axis direction); and a direction crossing the first direction and the second direction is called a third direction.

Also, it is favorable for the lengths in the second direction and the third direction to be about the same for the first electrode 1, the second electrode 2, the first magnetic layer 3, the second magnetic layer 4, and the nonmagnetic layer 5.

The first magnetic layer 3 in which the orientation of the magnetization is changeable, the second magnetic layer 4 in which the orientation of the magnetization is substantially fixed, and the nonmagnetic layer 5 that is between the first magnetic layer 3 and the second magnetic layer 4 together are called a MTJ (Magnetic Tunnel Junction) element.

A power supply 6 shown in FIG. 1 applies a direct current inside the MTJ element. One end of the power supply 6 is connected to the first electrode 1 via a first wire 7. Also, the other end of the power supply 6 is connected to the second electrode 2 via a second wire 8. The first wire 7 is connected also to a first ground 15.

The microwave sensor according to the embodiment also includes a sensor 9 that applies a direct current and senses a resistance change. The sensor 9 is, for example, a voltmeter. The voltmeter (the sensor 9) senses the potential difference between the first wire 7 and the second wire 8. The sensor 9 can sense, as a change of the direct current voltage, the precession of a magnetization excited inside the MTJ element by a microwave magnetic field.

In the embodiment, a large MR effect is obtained in the first magnetic layer 3 of the MTJ element recited above; and the first magnetic layer 3 includes a magnetic film configured so that the magnetization is oriented in the first direction (also called the surface normal direction) particularly in the state in which the microwave is not applied. In the microwave sensor according to the embodiment, the precession of the first magnetic layer 3 magnetization is excited by the microwave magnetic field; and the change of the amplitude is sensed as a resistance change due to the MR effect. Therefore, it is favorable for the Gilbert damping factor (α) of the first magnetic layer 3 to be as small as possible. FeB, etc., are materials having a small α.

Also, a perpendicular magnetization film that has a large coercivity is included in the second magnetic layer 4. Here, the perpendicular magnetization refers to the direction of the magnetization being oriented substantially in the surface normal direction recited above. For example, a Co/Pt or Co/Pd-based multilayer film, etc., may be used. Also, the second magnetic layer 4 may include a structure in which an antiferromagnetic film is stacked. Further, a synthetic antiferromagnetic film that has a structure in which a Ru film is interposed between two ferromagnetic layers may be used to adjust the leakage magnetic field from the second magnetic layer 4 to the first magnetic layer 3.

The nonmagnetic layer 5 may include a nonmagnetic metal such as Cu, Ag, etc., or an insulator such as MgO, Al₂O₃, etc. In particular, it is possible to obtain a large MR effect in the case where MgO is used. Further, it is possible to obtain a large MR ratio by interposing a CoFe film, a CoFeB film, etc., between the nonmagnetic layer 5 and the second magnetic layer 4 and further interposing an extremely thin Ta film or W film between the second magnetic layer 4 and these films.

Generally, a microwave sensor utilizes the excitation of the first magnetic layer 3 magnetization due to the spin torque generated by applying a microwave current inside the MTJ element.

Conversely, in the MTJ element according to the embodiment, a precession of the first magnetic layer 3 magnetization oriented in the surface normal direction recited above is excited by the microwave magnetic field.

In other words, in the embodiment, the magnetization path is a circular path in an ideal case where there is no anisotropy in the plane and the microwave current is applied inside the MTJ element. Here, being in the plane refers to the direction of the magnetization being oriented in a direction substantially orthogonal to the surface normal direction.

Also, because the second magnetic layer 4 magnetization is oriented in the surface normal direction, the high frequency component of the resistance change due to the MR effect (the resistance change due to the change of the relative angle of the first magnetic layer 3 magnetization and the second magnetic layer 4 magnetization) changing at the magnetization oscillation frequency is not large; and the change of the amplitude of the magnetization oscillation of the first magnetic layer 3 is directly the change of the direct current component of the MTJ element resistance.

As an example, the results of performing a simulation of the microwave sensor according to the embodiment will now be described.

The MTJ element of the calculated model has a circular columnar configuration having a diameter of 100 nm; and the film thicknesses of the first magnetic layer 3/nonmagnetic layer 5/second magnetic layer 4 were set respectively to 3 nm/2 nm/5 nm. The Ms (the saturation magnetization) of the first magnetic layer 3 was set to 1200 emu/cc; the second magnetic layer 4 was set to 100 emu/cc assuming a synthetic antiferromagnetic film; the perpendicular anisotropic magnetic field of the first magnetic layer 3 was set to 13000 Oe; and the second magnetic layer 4 magnetization was fixed in the +z axis direction parallel to the first direction.

Here, “+” refers to the upper side. Also, the Gilbert damping factor α was set to 0.02.

In the MTJ element, when the initial condition of the first magnetic layer 3 magnetization is shifted 5° from the +z axis direction and relaxation is performed in an external magnetic field of zero, the first magnetic layer 3 magnetization stabilizes to be oriented in the +z axis direction; and the magnetization is oriented in the surface normal direction when the microwave magnetic field is not applied.

In the MTJ element of this model, the amplitude of the microwave magnetic field was set to 1.5 Oe; the frequency was set to 1.45 GHz; and the microwave magnetic field was applied from 5 ns. The first magnetic layer 3 magnetization processes around the z-axis as the center due to the application of the microwave magnetic field. With the precession, a z-component Mz of the average magnetization of the first magnetic layer 3 decreases from 0.999 before the microwave magnetic field application to 0.988 after the application. Assuming a MR ratio of 100% at a MTJ element resistance of 1 kΩ (RA: about 8 Ωμm²), the resistance change amount is about 5.5Ω; and by setting the current applied to the MTJ element to be 0.16 mA (voltage: 160 mV), a voltage change of 0.88 mV can be sensed.

Generally, in a microwave sensor that uses a MTJ element, it is necessary to reduce the MTJ element size to further increase the sensitivity. However, if the element size is simply reduced, the MTJ element resistance may undesirably increase; and the injection loss of the microwave current due to the impedance mismatch may undesirably increase. As a solution, the development of a MTJ element having a low RA and a high MR ratio is necessary; but it is not easy to provide a low RA while maintaining a high MR ratio. In the microwave sensor according to the embodiment, it is unnecessary to cause the microwave current to flow inside the MTJ element. Therefore, it is possible to avoid the problems due to impedance mismatch; and it is possible to use a MTJ element having a high resistance. That is, it is possible to use a MTJ element that has a high RA and can realize a high MR ratio; and a highly-sensitive microwave sensor can be realized.

Also, the first magnetic layer 3 may include a perpendicular magnetization film in which the orientation of the magnetization is oriented in the surface normal direction. The perpendicular magnetization film of the first magnetic layer 3 may include a thin CoFeB or CoPt multilayer film, etc. In such a case, the first magnetic layer 3 magnetization can be easily oriented in the surface normal direction. Further, the magnetization orientations of the first magnetic layer 3 and the second magnetic layer 4 may be antiparallel orientations.

### SECOND EMBODIMENT

Here, the description will focus on the points that are different from the first embodiment.

FIG. 2 is a microwave sensor according to the second embodiment.

The microwave sensor according to the second embodiment further includes a magnetic field application mechanism 10.

The magnetic field application mechanism 10 is a mechanism that applies a direct current magnetic field to cause the orientation of the magnetization of the first magnetic layer 3 of the MTJ element to be oriented to be normal to the surface. The first magnetic layer 3 may include not only the perpendicular magnetization film but also an in-plane magnetization film to apply the direct current magnetic field.

In the example of FIG. 2, the microwave sensor according to the embodiment applies the direct current magnetic field by arranging a pair of excitation coils so that the MTJ element is interposed between the pair of excitation coils, and by energizing the excitation coils from a direct current excitation circuit.

By including such a magnetic field application mechanism 10 that applies the direct current magnetic field, it is easy to adjust the resonance frequency. Thereby, it is possible to use one microwave sensor to sense microwaves of different frequencies with high sensitivity. Also, similarly to the magnetization reversal of the first magnetic layer 3 magnetization due to the excitation by the microwave, magnetization reversal occurs when a microwave is applied by operating by applying a magnetic field in the reverse direction of the orientation of the magnetization. Thereby, an extremely large voltage change is obtained in the microwave sensor. However, because the orientation of the magnetization does not return to the original orientation naturally once the magnetization reversal has occurred, it is necessary perform an operation (spin injection and/or a magnetic field application) to return the orientation of the magnetization to the original orientation.

Irrespective of the example of FIG. 2, the magnetic field application mechanism 10 may not be a pair; and it is sufficient for one of the pair to be included. Also, the direct current magnetic field may be applied by using permanent magnets arranged so that the MTJ element is interposed.

Also, by using the leakage magnetic field of the second magnetic layer 4 as the magnetic field application mechanism 10 as well, the orientation of the magnetization of the first magnetic layer 3 of the MTJ element can be oriented to be normal to the surface of the excitation coil similarly to the excitation coil and/or permanent magnet.

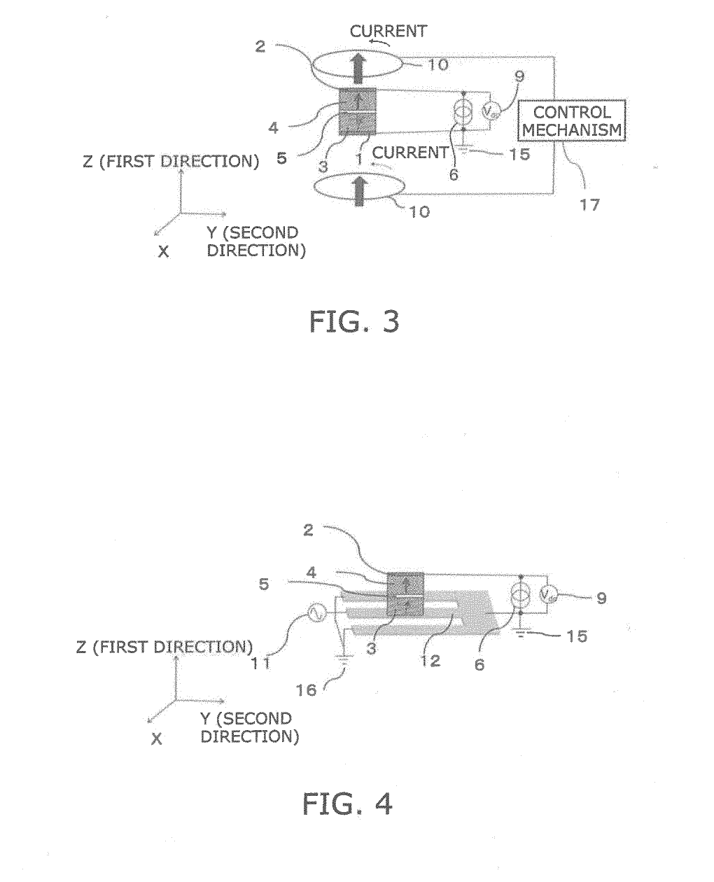

Also, as shown in FIG. 3, a control mechanism 17 that controls the magnetic field application mechanism 10 may be included. The control mechanism 17 is connected to the magnetic field application mechanism 10 and the power supply 6 and controls the direct current or controls the position of the excitation coil or the permanent magnet.

### THIRD EMBODIMENT

Here, the description will focus on the points that are different from the microwave sensor according to the first embodiment.

FIG. 4 shows a microwave sensor according to the third embodiment.

To achieve even higher sensitivity in the microwave sensor according to the first embodiment. It is necessary to apply, to the first magnetic layer 3, a microwave magnetic field that is as large as possible for the microwave of the same electrical power. Therefore, a transmission line 12 that transmits the microwave is formed under the MTJ element; and the signal line is patterned to be fine to have about the same line width as the element size. Thereby, as large a microwave magnetic field as possible can be applied to the MTJ element.

The microwave sensor according to the embodiment includes a microwave input terminal 11 and the transmission line 12 instead of the first electrode 1.

In the embodiment as shown in FIG. 4, the transmission line 12 has a three-prong configuration divided into three in the second direction. The microwave input terminal 11 is connected to one end of the center of the transmission line 12 divided into three. Also, a second ground 16 is connected to each of the two one-ends of the transmission line 12 that are configured to have the center of the transmission line 12 recited above interposed. Also, the other end of the transmission line 12 is connected to the first wire 7. Also, the MTJ element recited above is provided between the microwave input terminal 11 and the first wire 7. It is desirable for the widths where the transmission line 12 is divided into three each to be about as fine as the MTJ element size. The transmission line 12 is, for example, a coplanar line. The coplanar line is a planar transmission line in which a conductor film is printed on the surface on one side of a dielectric substrate used inside an integrated circuit.

The results of a simulation performed using the microwave sensor according to the embodiment will now be described.

The impedance of the transmission line 12 is 50Ω in the case where a microwave of 10 nW is input, the line width of the signal line of the transmission line 12 is set to 100 nm, and the thickness of the signal line of the transmission line 12 is set to 50 nm; the loss is small and can be ignored; and by estimating using the Biot-Savart law, a microwave magnetic field of about 0.75 Oe is applied to the first magnetic layer 3 having a diameter of 100 nm, having a thickness of 3 nm, and being separated from the transmission line 12 by 5 nm.

Further, a microwave magnetic field of 2 times, i.e., about 1.5 Oe, can be generated by shorting the transmission line at a location where the distance from the MTJ element is sufficiently shorter than the wavelength of the microwave. Thereby, the magnetization of the first magnetic layer 3 is excited by inputting a microwave of 10 nW. Thereby, it is possible to excite a magnetization oscillation.

In the embodiment, from the results of the simulation and the assumptions of the element model recited above, a resistance change of about 5.5Ω is possible; the voltage change is about 0.88 mV; and a sensitivity of 0.88 mV/10 nW=88000 V/W can be achieved, which is about the same as or higher than that of an element that uses the spin torque diode effect.

The transmission line 12 may be included on the MTJ element irrespective of the example of FIG. 4 recited above.

### FOURTH EMBODIMENT

The points that are different from the microwave sensors according to the first to third embodiments will be described.

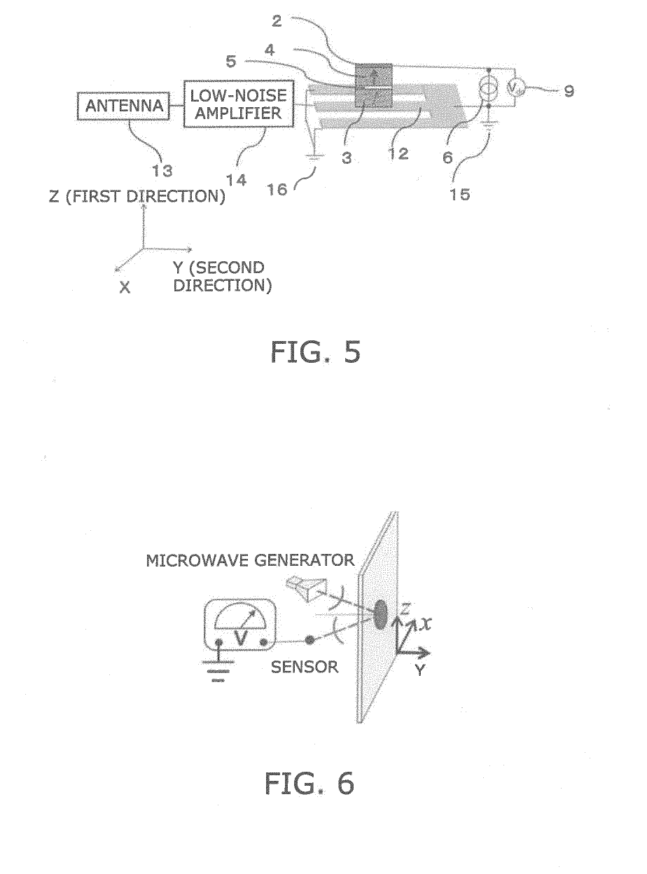

FIG. 5 shows a microwave sensor according to the fourth embodiment.

The microwave sensor according to the fourth embodiment further includes an antenna 13 that receives a microwave in space, and a low-noise amplifier 14 that amplifies the microwave current from the antenna 13.

The antenna 13 is connected to the low-noise amplifier 14; and the low-noise amplifier 14 is connected to the transmission line 12.

The antenna 13 is provided to receive an electromagnetic wave in space and perform electrical signal conversion.

The low-noise amplifier 14 suppresses the noise of a low-power microwave to be low and amplifies the low-power microwave. That is, the low-noise amplifier 14 is provided to be able to increase the sensing sensitivity.

By including the antenna 13 and the low-noise amplifier 14, it is also possible to efficiently sense microwaves in space.

### APPLICATION EXAMPLE

The microwave sensor is applicable to a micro sensor that can also sense frequencies by arranging the microwave sensors according to the embodiment having different resonance frequencies in an array configuration on the transmission line 12. Also, the microwave sensor is applicable to a microwave imaging device that can perform imaging by generating a microwave using a microwave generator such as that shown in FIG. 6, by irradiating the microwave on a measurement object to be measured, and by sensing the reflected wave.

In the configuration illustrated in FIG. 4, for example, the microwave input terminal 11 is connected to one of the three portions included in the transmission line 12. Two of the three portions included in the transmission line 12 are connected to the second ground 16. For example, the one of the three portions recited above is shorted to the two of the three portions recited above. The distance between the position of the short and the MTJ elements is sufficiently shorter than the wavelength of the microwave. By utilizing the reflection of the microwave in such a configuration, a microwave magnetic field of about 1.5 Oe can be generated, which is 2 times the microwave magnetic field of the case where shorting is not performed. Therefore, the magnetization dynamics are calculated by simulation for when a microwave magnetic field of 1.5 Oe is applied.

In the simulation described in reference to FIG. 4, the element of the model of the simulation is a pillar having a diameter of 100 nm. The thicknesses of the free layer/nonmagnetic layer/pinned layer respectively are 3 nm/2 nm/5 nm. The Ms of the free layer is 1200 emu/cc. A synthetic antiferromagnetic film is assumed as the pinned layer. The Ms of the pinned layer is 100 emu/cc. The perpendicular magnetic anisotropy of the free layer is 13000 Oe. The magnetization of the pinned layer is fixed in the +z axis direction. The damping constant α of the pinned layer is 0.02. In the simulation model, a microwave magnetic field having an amplitude of 1.5 Oe and a frequency of 1.45 GHz is applied to such an element. Due to the application of the microwave magnetic field, the free layer magnetization precesses with the Z-axis as a center. The Z-component of the average magnetization of the free layer is taken as a component Mz. The component Mz prior to the microwave magnetic field application is 0.999. After the microwave magnetic field application, the component Mz decreases to 0.988 following the precession recited above. The change of the electrical resistance is about 5.5Ω in the case where the element resistance is 1 kΩ and the MR ratio is 100%. The current that is supplied to the element is set to 0.16 mA (the voltage is 160 mV). At this time, a change of the voltage of 0.88 mV occurs. By sensing the change of the voltage, the microwave that is to be sensed can be sensed.

### FIFTH EMBODIMENT

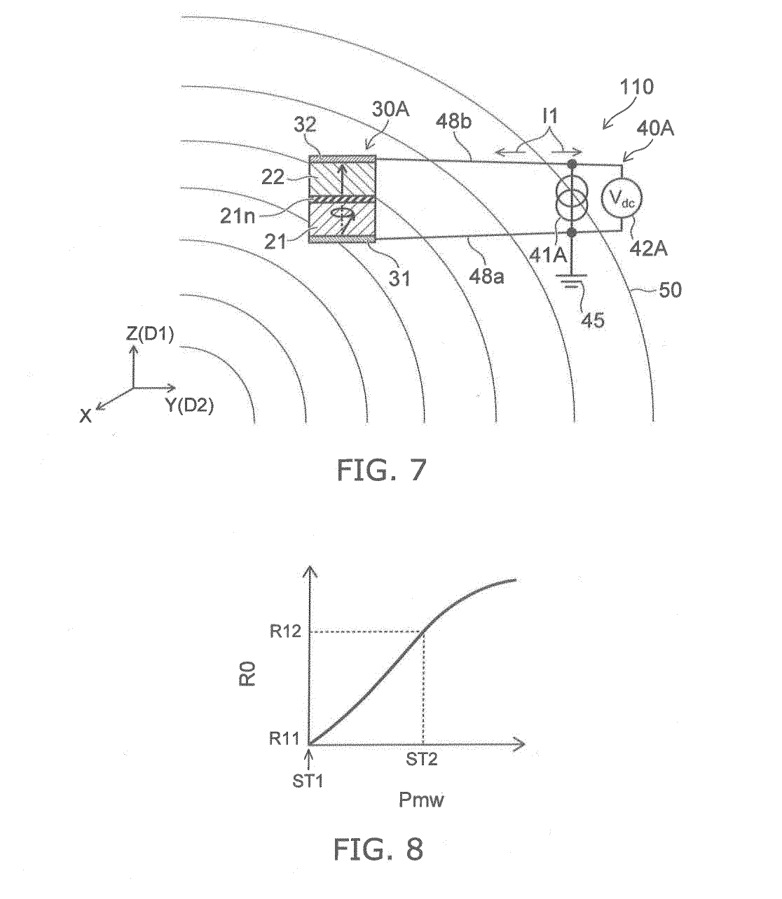

FIG. 7 is a schematic view illustrating a microwave sensor according to a fifth embodiment.

As shown in FIG. 7, the microwave sensor 110 according to the fifth embodiment includes a first stacked body 30A and a first controller 40A. The first controller 40A includes, for example, a first current supplier 41A and a first sensor 42A.

The first stacked body 30A includes a first magnetic layer 21, a second magnetic layer 22, and a first nonmagnetic layer 21n. The first nonmagnetic layer 21n is provided between the first magnetic layer 21 and the second magnetic layer 22.

The direction from the first magnetic layer 21 toward the second magnetic layer 22 is taken as a first direction D1.

The first direction D1 is taken as a Z-axis direction. One direction that is perpendicular to the Z-axis direction is taken as an X-axis direction. A direction that is perpendicular to the Z-axis direction and the X-axis direction is taken as a Y-axis direction.

In the example, the first stacked body 30A further includes a first electrode 31 and a second electrode 32. The first magnetic layer 21 is positioned between the first electrode 31 and the second electrode 32. The second magnetic layer 22 is positioned between the first magnetic layer 21 and the second electrode 32. The first electrode 31 is electrically connected to the first magnetic layer 21. The second electrode 32 is electrically connected to the second magnetic layer 22.

The first current supplier 41A is electrically connected to the first magnetic layer 21 and the second magnetic layer 22. A first interconnect 48a and a second interconnect 48b are provided in the example. One end of the first interconnect 48a is electrically connected to one end of the first current supplier 41A. The other end of the first interconnect 48a is electrically connected to the first magnetic layer 21 via the first electrode 31. One end of the second interconnect 48b is electrically connected to the other end of the first current supplier 41A. The other end of the second interconnect 48b is electrically connected to the second magnetic layer 22 via the second electrode 32.

The first current supplier 41A is configured to supply a current I1 to the first stacked body 30A. The current I1 flows through the first stacked body 30A from the first magnetic layer 21 toward the second magnetic layer 22. Or, the current I1 flows through the first stacked body 30A from the second magnetic layer 22 toward the first magnetic layer 21.

The first sensor 42A is electrically connected to the first magnetic layer 21 and the second magnetic layer 22. For example, an end of the first interconnect 48a is electrically connected to one end of the first sensor 42A. For example, an end of the second interconnect 48b is electrically connected to the other end of the first sensor 42A.

The one end of the first current supplier 41A and the one end of the first sensor 42A are set to a fixed potential 45 (e.g., the ground potential).

The first current supplier 41A is, for example, a power supply. The first sensor 42A is, for example, a voltmeter. Thus, the first controller 40A may include a voltmeter. For example, the first current supplier 41A and the first sensor 42A are connected in parallel.

For example, the first sensor 42A is configured to sense a value (e.g., at least one of a current, a voltage, or a resistance) corresponding to a first electrical resistance between the first magnetic layer 21 and the second magnetic layer 22.

A microwave 50 is applied to the first stacked body 30A. The microwave 50 is the sensing object. The microwave sensor 110 senses the microwave 50. In the embodiment, the frequency of the microwave is not less than 100 MHz and not more than 100 GHz.

The value recited above (e.g., the at least one of the current, the voltage, or the resistance) that corresponds to the first electrical resistance changes according to the microwave 50. The change of this value is sensed by the first sensor 42A.

FIG. 8 is a schematic view illustrating a characteristic of the microwave sensor according to the fifth embodiment.

The horizontal axis of FIG. 8 is an intensity Pmw (arbitrary units) of the microwave 50 applied to the first stacked body 30A. The vertical axis of FIG. 8 is an electrical resistance R0 (arbitrary units) of the first stacked body 30A. The change of the electrical resistance R0 corresponds to the change of the first electrical resistance between the first magnetic layer 21 and the second magnetic layer 22.

In the example as shown in FIG. 8, the electrical resistance R0 is high when the intensity Pmw of the microwave 50 is high.

For example, in a first state ST1, the intensity Pmw of the microwave 50 applied to the first stacked body 30A is low; or the microwave 50 is not applied to the first stacked body 30A. On the other hand, in a second state ST2, the intensity Pmw of the microwave 50 applied to the first stacked body 30A is higher than the intensity Pmw of the microwave 50 in the first state ST1.

The electrical resistance R0 in the first state ST1 is a first state electrical resistance R11. The electrical resistance R0 in the second state ST2 is a second state electrical resistance R12. In the example, the second state electrical resistance R12 is higher than the first state electrical resistance R11.

Thus, the electrical resistance R0 changes according to the microwave 50. In other words, the value that corresponds to the first electrical resistance changes according to the microwave 50. The change of this value is sensed by the first sensor 42A.

For example, it is considered that the change of the first electrical resistance is due to the magnetization of the magnetic layer included in the first stacked body 30A changing according to the microwave 50. An example of the magnetization of the magnetic layer will now be described.

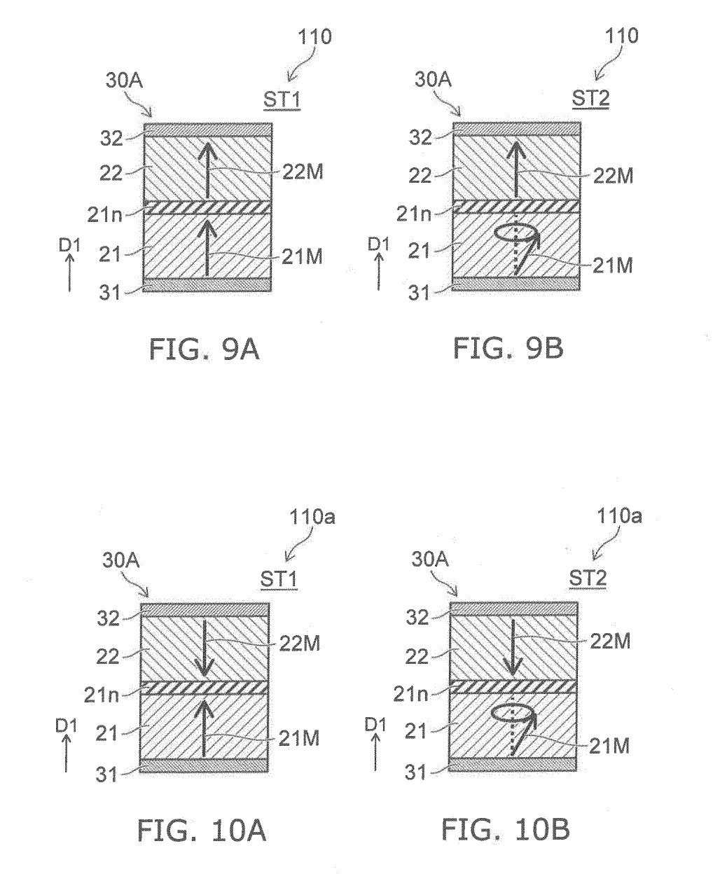

FIG. 9A and FIG. 9B are schematic cross-sectional views illustrating the microwave sensor according to the fifth embodiment.

FIG. 9A corresponds to the state (the first state ST1) in which the microwave 50 is not applied to the first stacked body 30A. FIG. 9B corresponds to the state (the second state ST2) in which the microwave 50 is applied to the first stacked body 30A.

As shown in FIG. 9A and FIG. 9B, the second magnetization 22M of the second magnetic layer 22 is aligned with the first direction D1 (the Z-axis direction from the first magnetic layer 21 toward the second magnetic layer 22) in the first state ST1 and the second state ST2. The direction of the second magnetization 22M does not change even when an external magnetic field (e.g., including the microwave 50 of the sensing object) is applied to the first stacked body 30A. The second magnetization 22M is fixed along the Z-axis direction.

On the other hand, the first magnetization 21M of the first magnetic layer 21 changes according to, for example, the microwave 50. For example, as shown in FIG. 9A, the first magnetization 21M is aligned with the first direction D1 in the first state ST1. In the example, the angle between the first magnetization 21M and the second magnetization 22M is small, e.g., substantially zero. Therefore, the first electrical resistance in the first state ST1 is low.

As shown in FIG. 9B, for example, the first magnetization 21M processes in the second state ST2 in which the intensity Pmw of the microwave 50 is high. The precession is caused by the microwave 50 and the current I1 supplied to the first stacked body 30A from the first current supplier 41A. The current I1 is, for example, substantially direct current.

Due to the precession recited above, the angle between the first magnetization 21M and the second magnetization 22M in the second state ST2 is large compared to the first state ST1. Therefore, the first electrical resistance in the second state ST2 is higher than the first electrical resistance in the second state ST2.

For example, such a change of the first electrical resistance is based on the MR effect. In the example recited above, for example, the first electrical resistance has a direct current component and an alternating current component. The frequency of the alternating current component may correspond to, for example, the frequency of the microwave 50. For example, the direct current component of the first electrical resistance is extracted. For example, the first sensor 42A may sense the microwave 50 by using the change of the direct current component. In the characteristic illustrated in FIG. 8, the electrical resistance R0 corresponds to, for example, the direct current component.

Thus, in the microwave sensor 110 according to the embodiment, the second magnetization 22M of the second magnetic layer 22 is aligned with the first direction D1 (the Z-axis direction). For example, the second magnetic layer 22 is a perpendicular magnetization film. For example, in the state (e.g., the first state ST1) in which the microwave 50 is not applied to the first stacked body 30A, the first magnetization 21M of the first magnetic layer 21 is aligned with the first direction D1. The first electrical resistance changes according to the microwave 50 applied to the first stacked body 30A.

On the other hand, there is a reference example in which the second magnetization 22M of the second magnetic layer 22 is substantially perpendicular to the first direction D1 in the first state ST1 and the second state ST2. In the reference example, the second magnetic layer 22 is an in-plane magnetization film. In the reference example, for example, a microwave current is injected into the stacked body. The oscillation of the magnetization is excited by the spin torque. The microwave 50 is sensed by sensing the voltage generated by the spin torque diode effect. In the spin torque diode effect, a direct current voltage is generated by the resistance of the stacked body changing at the same frequency as the microwave current.

Conversely, in the embodiment, the second magnetization 22M of the second magnetic layer 22 is aligned with the first direction D1 (the Z-axis direction). The second magnetization 22M is excited by the microwave 50. The direct current component of the resistance of a first stacked body 50A changes. Thereby, the microwave 50 can be sensed with high sensitivity. According to the embodiment, a microwave sensor can be provided in which the sensing sensitivity can be improved. In the embodiment, the mixing noise is extremely small because the resistance change at the high frequency is extremely small.

Generally, because of the high sensitivity, the approach of using the spin torque diode effect is often employed when sensing the microwave 50. Therefore, an in-plane magnetization film is used as the second magnetic layer 22. Conversely, in the embodiment, the approach of using the spin torque diode effect is not employed; the magnetic field oscillation excitation due to the microwave magnetic field is utilized; and the approach of sensing the state of the magnetic field oscillation excitation as, for example, the change of the direct current component of the resistance via the MR effect is employed.

In the embodiment, a MR element structure is employed in which the increase of the amplitude of the magnetization excited by the microwave magnetic field efficiently contributes to the change of the direct current component of the resistance. The resistance change at the high frequency does not occur easily in this configuration. The voltage change due to the spin torque diode effect substantially does not occur in this configuration. Therefore, such a configuration generally is not employed. Such an element is focused upon deliberately in the embodiment.

In the embodiment, a microwave current may not be supplied to the MR element because the spin torque diode effect is not used. Thereby, the resistance per area (the resistance per unit surface area) of the film included in the element can be large. A large MR effect is obtained in a film having a large resistance per area. Therefore, it is possible to use a MR element having a high MR ratio; and high sensitivity is obtained even without the spin torque diode effect.

On the other hand, to obtain high sensitivity by using the spin torque diode effect, it is necessary to downscale the element. In such a case, the increase of the element resistance is a large problem. If the resistance becomes high, the microwave is reflected due to impedance mismatch; and the microwave current that is applied to the element undesirably decreases. If the resistance per area is reduced to suppress the reflection of the microwave, as a result, it is difficult to obtain a high MR ratio.

In the embodiment, the current I1 that is supplied to the first stacked body 30A from the first current supplier 41A is, for example, direct current. In the embodiment, the current I1 may include noise (e.g., an oscillation component). In the embodiment, ½ of the amplitude of the noise is not more than 10% of the magnitude of the direct current component of the current I1. In the embodiment, ½ of the amplitude of the noise may be not more than 5% of the magnitude of the direct current component of the current I1. In the embodiment, ½ of the amplitude of the noise may be not more than 2% of the magnitude of the direct current component of the current I1.

As recited above, the orientation of the first magnetization 21M of the first magnetic layer 21 is aligned with the first direction D1 in the first state ST1. In the second state ST2, the orientation of the first magnetization 21M is different from the orientation of the first state ST1. In one example, the first magnetic layer 21 includes a perpendicular magnetization film. Thereby, in the first state ST1, the orientation of the first magnetization 21M of the first magnetic layer 21 is aligned with the first direction D1. In another example, the first magnetic layer 21 may include an in-plane magnetization film. In such a case, for example, the first magnetization 21M of the first magnetic layer 21 including the in-plane magnetization film is caused to be aligned with the first direction D1 in the first state ST1 by a magnetic field application portion described below, etc.

For the characteristic illustrated in FIG. 8, there may be a case where the electrical resistance R0 changes abruptly with the change of the intensity Pmw. For example, the abrupt change of the electrical resistance R0 corresponds to the reverse of the first magnetization 21M of the first magnetic layer 21.

In one example (the microwave sensor 110) as shown in FIG. 9A and FIG. 9B, the orientation of the second magnetization 22M is oriented from the first magnetic layer 21 toward the second magnetic layer 22. In the first state ST1, the orientation of the first magnetization 21M also is oriented from the first magnetic layer 21 toward the second magnetic layer 22.

Several examples of the magnetizations of the first stacked body 30A will now be described.

FIG. 10A and FIG. 10B are schematic cross-sectional views illustrating another microwave sensor according to the fifth embodiment.

FIG. 10A and FIG. 10B correspond respectively to the first state ST1 and the second state ST2. In the microwave sensor 110a, the orientation of the second magnetization 22M is oriented from the second magnetic layer 22 toward the first magnetic layer 21. In the first state ST1, the orientation of the first magnetization 21M is oriented from the first magnetic layer 21 toward the second magnetic layer 22.

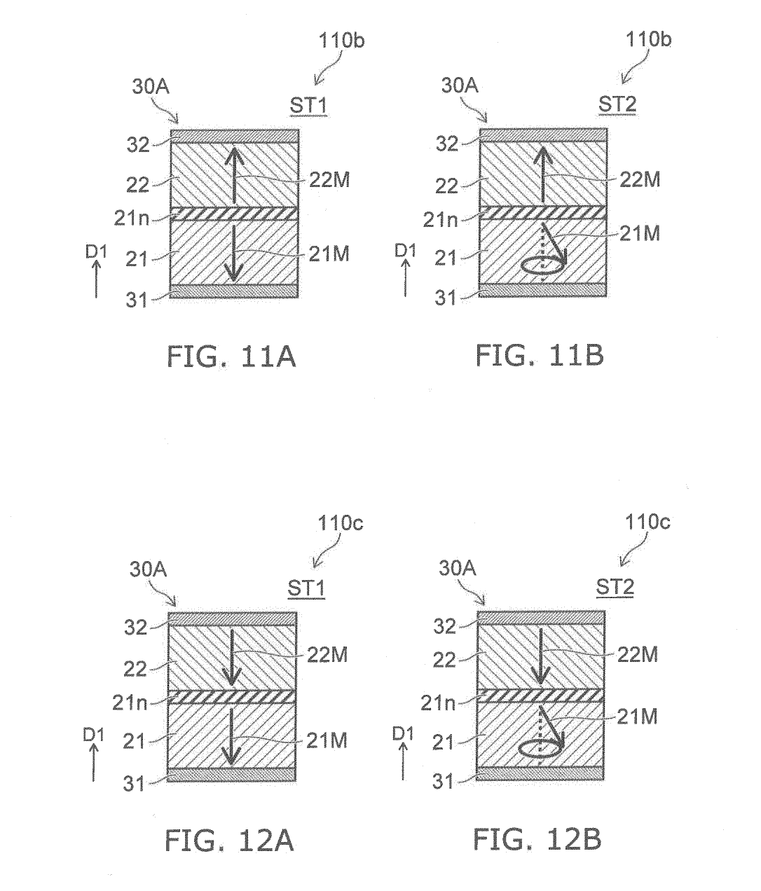

FIG. 11A and FIG. 11B are schematic cross-sectional views illustrating another microwave sensor according to the fifth embodiment.

FIG. 11A and FIG. 11B correspond respectively to the first state ST1 and the second state ST2. In the microwave sensor 110b, the orientation of the second magnetization 22M is oriented from the first magnetic layer 21 toward the second magnetic layer 22. In the first state ST1, the orientation of the first magnetization 21M is oriented from the second magnetic layer 22 toward the first magnetic layer 21.

FIG. 12A and FIG. 12B are schematic cross-sectional views illustrating another microwave sensor according to the fifth embodiment.

FIG. 12A and FIG. 12B correspond respectively to the first state ST1 and the second state ST2. In the microwave sensor 110c, the orientation of the second magnetization 22M is oriented from the second magnetic layer 22 toward the first magnetic layer 21. In the first state ST1, the orientation of the first magnetization 21M also is oriented from the second magnetic layer 22 toward the first magnetic layer 21.

In the microwave sensor 110c, the electrical resistance R0 is high if the intensity Pmw of the microwave 50 is high. In the microwave sensors 110a and 110b, the electrical resistance R0 is low if the intensity Pmw of the microwave 50 is high.

In the first state ST1, the behavior of the change of the electrical resistance R0 changes due to the relationship between the first magnetization 21M and the second magnetization 22M.

The first nonmagnetic layer 21n may include, for example, an insulating material. For example, the first nonmagnetic layer 21n includes at least one selected from the group consisting of MgO and Al₂O₃. In such a case, the first stacked body 30A may function as a TMR element.

For example, the first nonmagnetic layer 21n may include a conductive material. For example, the first nonmagnetic layer 21n includes at least one selected from the group consisting of Cu and Ag. In such a case, the first stacked body 30A may function as a MR element.

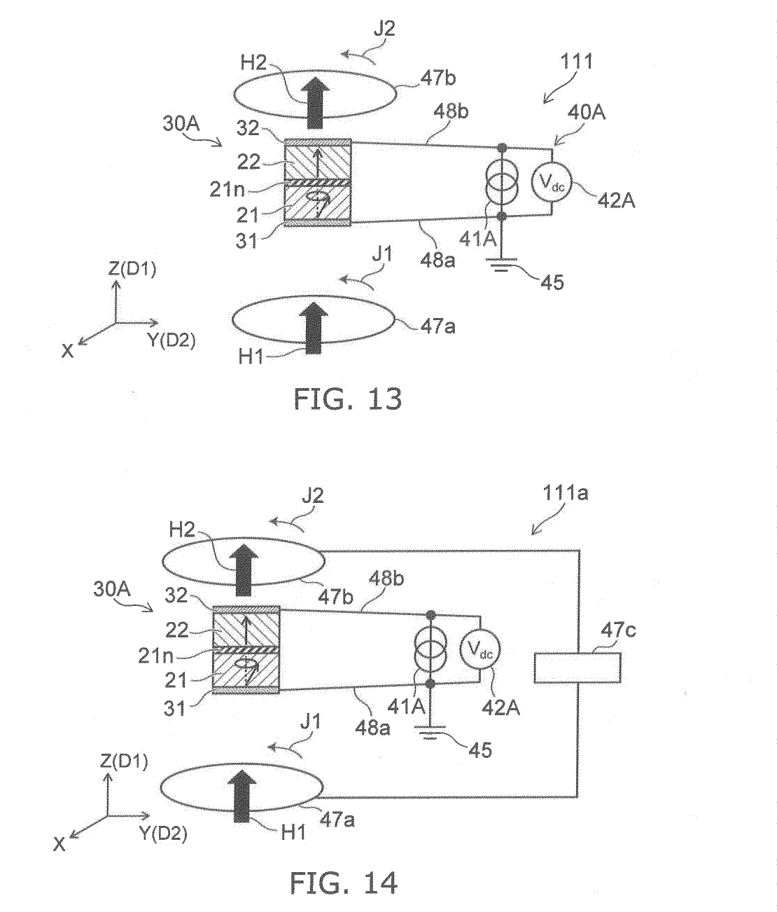

FIG. 13 is a schematic view illustrating another microwave sensor according to the fifth embodiment.

As shown in FIG. 13, the microwave sensor 111 includes a first magnetic field generator 47a in addition to the first stacked body 30A and the first controller 40A. A second magnetic field generator 47b is further provided in the example. Otherwise, the configuration of the microwave sensor 111 may be similar to, for example, the microwave sensor 110 (and 110a to 111c).

The first magnetic field generator 47a is, for example, a coil. For example, a current J1 is supplied to the first magnetic field generator 47a. Thereby, a first magnetic field H1 is generated from the first magnetic field generator 47a.

The first magnetic field H1 that is generated from the first magnetic field generator 47a is applied to the first stacked body 30A. The first magnetic field H1 has a component along the first direction D1 at the position of at least a portion of the first stacked body 30A. For example, in the first state ST1, the first magnetization 21M of the first magnetic layer 21 is aligned with the first direction D1 easily due to the first magnetic field H1.

The second magnetic field generator 47b is further provided in the example. The position of the first direction D1 of the first stacked body 30A is between the position of the first direction D1 of the first magnetic field generator 47a and the position of the first direction D1 of the second magnetic field generator 47b. For example, the first stacked body 30A is positioned between the first magnetic field generator 47a and the second magnetic field generator 47b in the first direction D1.

The second magnetic field generator 47b is, for example, a coil. For example, a current J2 is supplied to the second magnetic field generator 47b. Thereby, a second magnetic field H2 is generated from the second magnetic field generator 47b.

The second magnetic field H2 that is generated from the second magnetic field generator 47b is applied to the first stacked body 30A. The second magnetic field H2 has a component along the first direction D1 at the position of at least a portion of the first stacked body 30A. For example, in the first state ST1, the first magnetization 21M of the first magnetic layer 21 is aligned with the first direction D1 easily due to the second magnetic field H2.

The orientation of the first magnetic field H1 is the same as the orientation of the second magnetic field H2. For example, a stable magnetic field is applied to the first magnetic layer 21. For example, in the first state ST1, the first magnetization 21M of the first magnetic layer 21 is stably and easily aligned with the first direction D1.

FIG. 14 is a schematic view illustrating another microwave sensor according to the fifth embodiment.

As shown in FIG. 14, the microwave sensor 111a includes a magnetic field controller 47c in addition to the first stacked body 30A, the first controller 40A, the first magnetic field generator 47a, and the second magnetic field generator 47b. Otherwise, the configuration of the microwave sensor 111a may be, for example, similar to that of the microwave sensor 111.

The magnetic field controller 47c controls, for example, at least one of the first magnetic field generator 47a or the second magnetic field generator 47b. For example, the magnetic field controller 47c changes at least one of the magnitude of the first magnetic field H1 or the orientation of the first magnetic field H1. For example, the magnetic field controller 47c may change at least one of the magnitude of the second magnetic field H2 or the orientation of the second magnetic field H2.

For example, the magnetic field controller 47c may change at least one of the current J1 caused to flow in the first magnetic field generator 47a or the current J2 caused to flow in the second magnetic field generator 47b.

For example, the magnetic field controller 47c may change at least one of the distance between the first magnetic field generator 47a and the first stacked body 30A or the distance between the second magnetic field generator 47b and the first stacked body 30A.

For example, by changing the magnitude of at least one of the first magnetic field H1 or the second magnetic field H2, for example, the resonance frequency of the first stacked body 30A can be changed. For example, multiple microwaves 50 of different frequencies can be sensed with high sensitivity by one microwave sensor 111a.

For example, the first magnetization 21M of the first magnetic layer 21 can be controlled to be in the desired direction by at least one of the first magnetic field H1 or the second magnetic field H2. For example, the orientation of the first magnetization 21M in the first state ST1 can be set by at least one of the first magnetic field H1 or the second magnetic field H2 to be the reverse of the direction of the magnetization excited by the microwave 50. Thereby, the change of the first electrical resistance can be large between the first state ST1 and the second state ST2. Thereby, the microwave 50 can be sensed with extremely high sensitivity.

In such an operation, the reversal that occurred in the first magnetization 21M is easily returned to the original orientation by the magnetic field controller 47c changing at least one of the first magnetic field H1 or the second magnetic field H2.

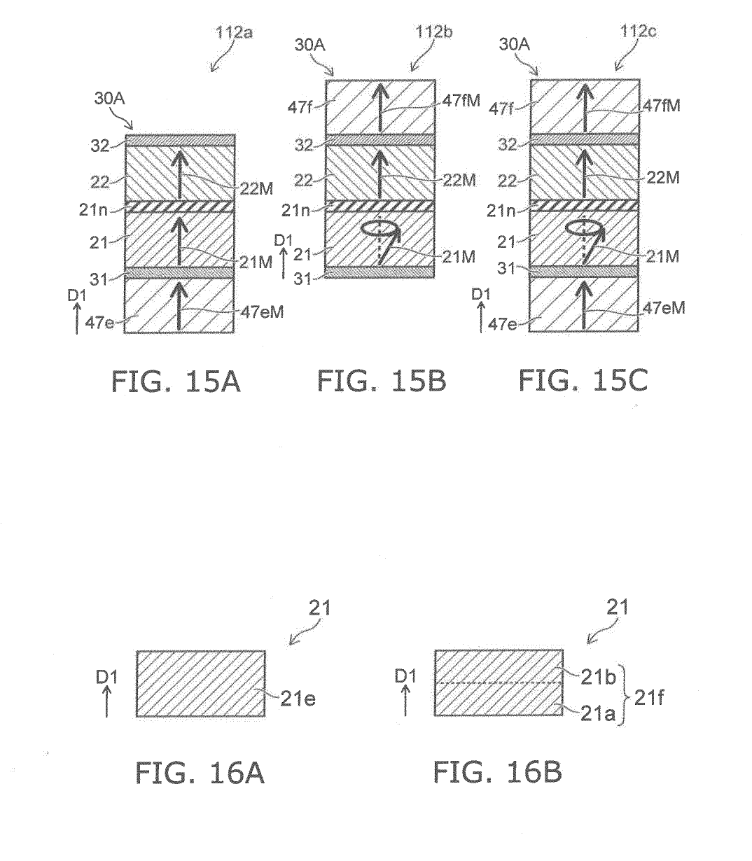

FIG. 15A to FIG. 15C are schematic cross-sectional views illustrating other microwave sensors according to the fifth embodiment.

The first controller 40A (e.g., referring to FIG. 7) is not illustrated in these drawings.

In a microwave sensor 112a as shown in FIG. 15A, a first magnetic portion 47e (a magnetic portion) is included in addition to the first stacked body 30A. Otherwise, the configuration of the microwave sensor 112a may be similar to, for example, the microwave sensor 110 (and 110a to 111c).

The direction from the first magnetic portion 47e toward the first magnetic layer 21 is aligned with the first direction D1. For example, the first magnetic layer 21 is positioned between the second magnetic layer 22 and the first magnetic portion 47e in the first direction D1. A magnetization 47eM of the first magnetic portion 47e is aligned with the first direction D1.

As shown in FIG. 15B, the microwave sensor 112b includes a second magnetic portion 47f (a magnetic portion) in addition to the first stacked body 30A. Otherwise, the configuration of the microwave sensor 112b may be similar to, for example, the microwave sensor 110 (and 110a to 111c).

The direction from the second magnetic portion 47f toward the first magnetic layer 21 is aligned with the first direction D1. For example, the second magnetic layer 22 is positioned between the first magnetic layer 21 and the second magnetic portion 47f in the first direction D1. A magnetization 47fM of the second magnetic portion 47f is aligned with the first direction D1.

As shown in FIG. 15C, the first magnetic portion 47e (the magnetic portion) and the second magnetic portion 47f (the magnetic portion) are provided in the microwave sensor 112c.

In the first state ST1, the first magnetization 21M of the first magnetic layer 21 is easily aligned with the first direction D1 by these magnetic portions.

The first magnetic portion 4e (the magnetic portion) and the second magnetic portion 47f (the magnetic portion) include, for example, magnetic bodies. These magnetic portions include, for example, magnets.

The distance between the first magnetic portion 47e and the first stacked body 30A may be modifiable. The distance between the second magnetic portion 47f and the first stacked body BOA may be modifiable. The modification of these distances may be implemented by, for example, the magnetic field controller 47c (referring to FIG. 14).

In the microwave sensors 111, 111a, 112a, 112b, and 112c, a magnetic field is applied from the outside to the first stacked body 30A. In the first state ST1, the first magnetization 21M is easily aligned with the first direction D1 by the magnetic field. To this end, in these microwave sensors, the first magnetic layer 21 may include an in-plane magnetization film.

For example, the first magnetic layer 21 includes at least one selected from the group consisting of Fe, Co, and Ni. The in-plane magnetization film is obtained by using these materials and by using, for example, the appropriate thickness. Then, the first magnetization 21M is aligned with the first direction D1 in the first state ST1 by the magnetic field applied from the outside.

On the other hand, as described above, the first magnetic layer 21 may include a perpendicular magnetization film. Examples of configurations of such a case will now be described.

FIG. 16A and FIG. 16B are schematic cross-sectional views illustrating other microwave sensors according to the fifth embodiment.

In one example as shown in FIG. 16A, the first magnetic layer 21 includes a CoFeB film 21e. As shown in FIG. 16B, the first magnetic layer 21 may include a CoPt-containing film 21f.

As shown in FIG. 168, the CoPt-containing film 21f includes a Co film 21a and a Pt film 21b. The direction from the Co film 21a toward the Pt film 21b is aligned with the first direction D1. These films are stacked along the first direction D1.

Thus, the first magnetic layer 21 includes, for example, at least one selected from the group consisting of the Co FeB film 21e and the CoPt-containing film 21f. Thereby, a perpendicular magnetization film is obtained.

An example of the second magnetic layer 22 will now be described.

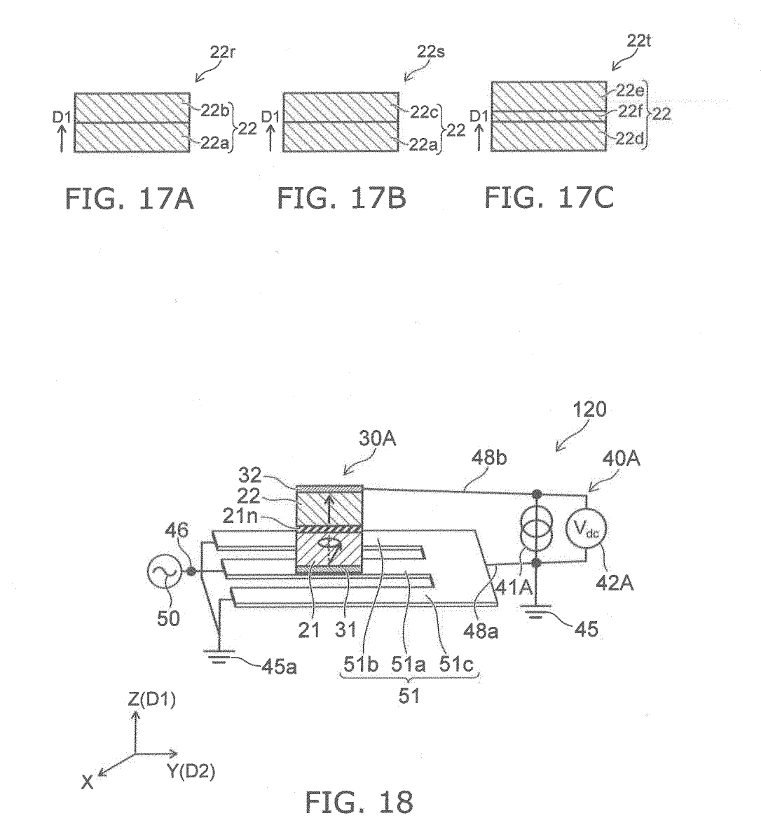

FIG. 17A to FIG. 17C are schematic cross-sectional views illustrating other microwave sensors according to the fifth embodiment.

The second magnetic layer 22 may include a first structure 22r, a second structure 22s, or a third structure 22t described below.

As shown in FIG. 17A, the first structure 22r includes a Co film 22a and a Pt film 22b. The direction from the Co film 22a toward the Pt film 22b is aligned with the first direction D1.

As shown in FIG. 17B, the second structure 22s includes the Co film 22a and a Pd film 22c. The direction from the Co film 22a toward the Pd film 22c is aligned with the first direction D1.

As shown in FIG. 17C, the third structure 22t includes a first magnetic film 22d, a second magnetic film 22e, and a Ru film 22f. The Ru film 22f is provided between the first magnetic film 22d and the second magnetic film 22e. The direction from the first magnetic film 22d toward the second magnetic film 22e is aligned with the first direction D1.

The second magnetic layer 22 may include at least one selected from the group consisting of the first structure 22r, the second structure 22s, and the third structure 22t recited above. A stable second magnetization 22M is obtained by such a structure. For example, the leakage magnetic field of the third structure 22t can be suppressed.

### SIXTH EMBODIMENT

FIG. 18 is a schematic view illustrating a microwave sensor according to a sixth embodiment.

As shown in FIG. 18, the microwave sensor 120 includes a transmission line 51 in addition to the first stacked body 30A and the first controller 40A. Otherwise, the configuration of the microwave sensor 120 may be similar to, for example, the configuration described in reference to the fifth embodiment.

The transmission line 51 includes a first conductive layer 51a. The direction from the first conductive layer 51a toward the first magnetic layer 21 is aligned with the first direction D1. The direction from the first conductive layer 51a toward the second magnetic layer 22 is aligned with the first direction D1.

In the example, the first magnetic layer 21 is positioned between the second magnetic layer 22 and the first conductive layer 51a. In the embodiment, the second magnetic layer 22 may be positioned between the first magnetic layer 21 and the first conductive layer 51a.

In the example, the first stacked body 30A includes the first electrode 31. The first electrode 31 is positioned between the first magnetic layer 21 and the first conductive layer 51a. In the embodiment, the first electrode 31 may be omitted. For example, the conductive member that is used to form the first electrode 31 may be used to form the first conductive layer 51a.

In the example, the transmission line 51 further includes a second conductive layer 51b and a third conductive layer 51c. The first conductive layer 51a is positioned between the second conductive layer 51b and the third conductive layer 51c in a direction (e.g., one direction in the X-Y plane) crossing the first direction D1.

In the example, the transmission line 51 (the conductive layer recited above) extends along a second direction D2.

For example, the second conductive layer 51b and the third conductive layer 51c are set to a fixed potential 45a (e.g., the ground potential). For example, the first conductive layer 51a is connected to a microwave input terminal 46. A signal that corresponds to the microwave 50 to be sensed may be input to the microwave input terminal 46.

In the microwave sensor 120, the microwave 50 (or the signal (the microwave) corresponding to the microwave 50) to be sensed propagates through the first conductive layer 51a. A magnetic field (a microwave magnetic field) that is based on the microwave propagating through the first conductive layer 51a is applied to the first stacked body 30A. The electrical resistance R0 (i.e., the first electrical resistance) of the first stacked body 30A changes according to the magnetic field (the microwave magnetic field) based on the microwave propagating through the first conductive layer 51a. Thereby, the microwave 50 to be sensed is sensed.

FIG. 19 is a schematic view illustrating another microwave sensor according to the sixth embodiment.

As shown in FIG. 19, the microwave sensor 121 includes an antenna 61 and an amplifier 62 in addition to the first stacked body 30A, the first controller 40A, and the transmission line 51. Otherwise, the configuration of the microwave sensor 121 may be similar to, for example, the configuration described in reference to the microwave sensor 120.

The antenna 61 receives the microwave 50. The amplifier 62 amplifies the signal generated by the antenna 61. The signal that is generated by the antenna 61 is based on the microwave 50 received by the antenna 61. The amplifier 62 is, for example, a low-noise amplifier. The output portion of the amplifier 62 is electrically connected to the first conductive layer 51a.

The microwave 50 to be sensed is converted into a signal including a high frequency wave by the antenna 61. This signal is amplified by the amplifier 62. The amplified signal is input to the first conductive layer 51a. The electrical resistance R0 (i.e., the first electrical resistance) of the first stacked body 30A is changed by the signal input to the first conductive layer 51a (the signal corresponding to the microwave 50).

In the microwave sensor 121, the microwave 50 can be sensed efficiently with high sensitivity.

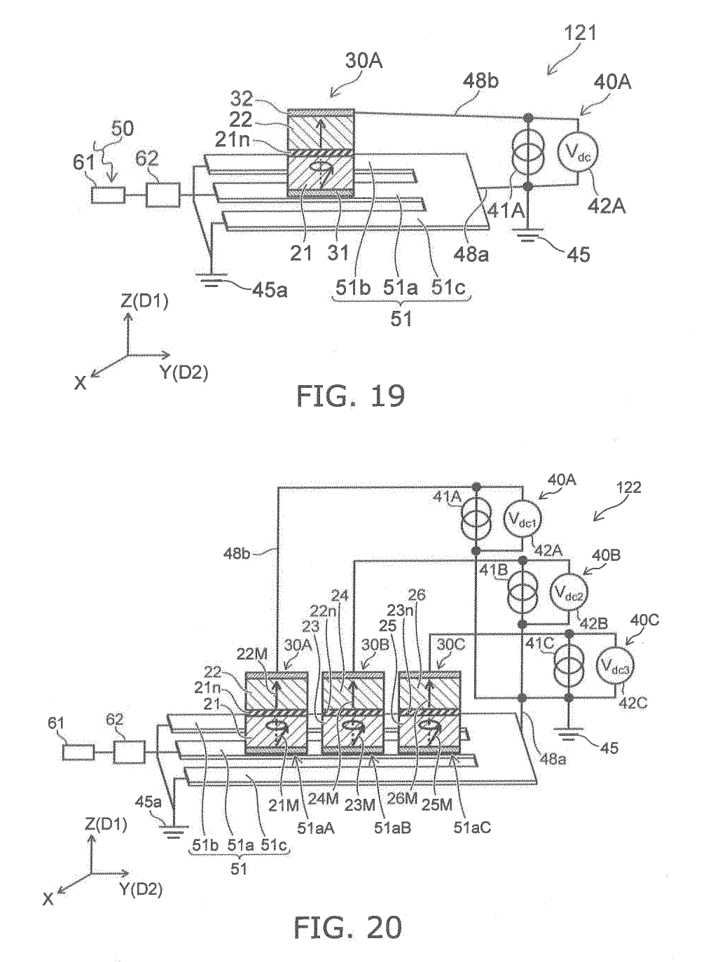

FIG. 20 is a schematic view illustrating another microwave sensor according to the sixth embodiment.

As shown in FIG. 20, the microwave sensor 122 includes multiple stacked bodies (the first stacked body 30A, a second stacked body 30B, a third stacked body 30C, etc.) and multiple controllers (the first controller 40A, a second controller 40B, a third controller 40C, etc.). Also, the transmission line 51, the antenna 61, and the amplifier 62 are provided. Otherwise, the configuration of the microwave sensor 122 may be similar to, for example, the configuration described in reference to the microwave sensor 121.

The second stacked body 30B includes a third magnetic layer 23, a fourth magnetic layer 24, and a second nonmagnetic layer 22n. The second nonmagnetic layer 22n is provided between the third magnetic layer 23 and the fourth magnetic layer 24. The direction from the third magnetic layer 23 toward the fourth magnetic layer 24 is aligned with the first direction D1. A fourth magnetization 24M of the fourth magnetic layer 24 is aligned with the first direction D1. A fifth magnetization 25M of a fifth magnetic layer 25 is changeable.

The third stacked body 30C includes the fifth magnetic layer 25, a sixth magnetic layer 26, and a third nonmagnetic layer 23n. The third nonmagnetic layer 23n is provided between the fifth magnetic layer 25 and the sixth magnetic layer 26. The direction from the fifth magnetic layer 25 toward the sixth magnetic layer 26 is aligned with the first direction D1. A sixth magnetization 26M of the sixth magnetic layer 26 is aligned with the first direction D1. The fifth magnetization 25M of the fifth magnetic layer 25 is changeable.

The second controller 40B is electrically connected to the third magnetic layer 23 and the fourth magnetic layer 24 and is configured to supply a current to the second stacked body 30B. The second controller 40B is configured to sense a value corresponding to a second electrical resistance between the third magnetic layer 23 and the fourth magnetic layer 24.

For example, the second controller 40B includes a second current supplier 41B and a second sensor 42B. The second current supplier 41B is electrically connected to the third magnetic layer 23 and the fourth magnetic layer 24 and is configured to supply a current to the second stacked body 30B. The second sensor 42B is configured to sense a value corresponding to the second electrical resistance between the third magnetic layer 23 and the fourth magnetic layer 24.

The third controller 40C is electrically connected to the fifth magnetic layer 25 and the sixth magnetic layer 26 and is configured to supply a current to the third stacked body 30C. The third controller 40C is configured to sense a value corresponding to a third electrical resistance between the fifth magnetic layer 25 and the sixth magnetic layer 26.

For example, the third controller 40C includes a third current supplier 41C and a third sensor 42C. The third current supplier 41C is electrically connected to the fifth magnetic layer 25 and the sixth magnetic layer 26 and is configured to supply a current to the third stacked body 30C. The third sensor 42C is configured to sense a value corresponding to the third electrical resistance between the fifth magnetic layer 25 and the sixth magnetic layer 26.

The value that corresponds to the second electrical resistance changes according to the microwave 50. The value that corresponds to the third electrical resistance changes according to the microwave 50.

For example, a first resonance frequency f1 of the first stacked body 30A is different from a second resonance frequency f2 of the second stacked body 30B. For example, a third resonance frequency f3 of the third stacked body 30C is different from the first resonance frequency f1 and different from the second resonance frequency f2. For example, the configurations of the magnetic layers included in one of the multiple stacked bodies are set to be different from the configurations of the magnetic layers included in another one of the multiple stacked bodies. Thereby, a difference is obtained between the resonance frequencies. For example, the magnitude of the current supplied to the one of the multiple stacked bodies is set to be different from the magnitude of the current supplied to the other one of the multiple stacked bodies. Thereby, the difference is obtained between the resonance frequencies.

For example, at least one of the multiple stacked bodies may be used according to the frequency of the microwave 50 to be sensed. Processing such as comparing the signals obtained from the multiple stacked bodies may be performed. For example, information that relates to the frequency of the microwave 50 can be obtained.

In the microwave sensor 122, the directions from the first conductive layer 51a toward the multiple stacked bodies (the first stacked body 30A, the second stacked body 30B, the third stacked body 30C, etc.) are aligned with the first direction D1. The direction from one of the multiple stacked bodies toward another one of the multiple stacked bodies is aligned with a second direction D2 (the direction in which the first conductive layer 51a extends).

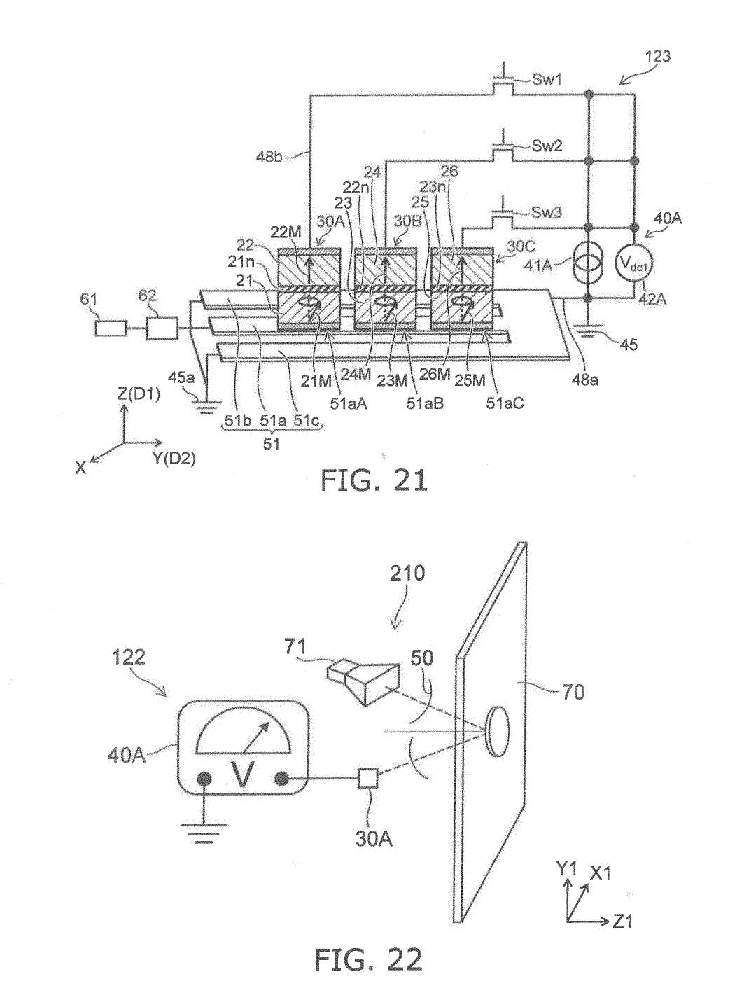

FIG. 21 is a schematic view illustrating another microwave sensor according to the sixth embodiment.

As shown in FIG. 21, the microwave sensor 123 includes multiple stacked bodies (the first stacked body 30A, the second stacked body 30B, the third stacked body 30C, etc.) and one controller (e.g., the first controller 40A). Otherwise, the configuration of the microwave sensor 123 may be similar to, for example, the configuration described in reference to the microwave sensor 122.

For example, the first controller 40A is electrically connected to the third magnetic layer 23 and the fourth magnetic layer 24 and is further configured to supply a current to the second stacked body 30B. The first controller 40A is further configured to sense a value corresponding to the second electrical resistance between the third magnetic layer 23 and the fourth magnetic layer 24.

For example, the first controller 40A is electrically connected to the fifth magnetic layer 25 and the sixth magnetic layer 26 and further configured to supply a current to the third stacked body 30C. The first controller 40A is further configured to sense a value corresponding to the third electrical resistance between the fifth magnetic layer 25 and the sixth magnetic layer 26.

For example, a first switch sw1 is provided on an interconnect (a current path) between the first controller 40A and the first stacked body 30A. A second switch sw2 is provided on an interconnect (the current path) between the first controller 40A and the second stacked body 30B. A third switch sw3 is provided on an interconnect (a current path) between the first controller 40A and the third stacked body 30C.

By switching these switches, the value corresponding to the electrical resistance of one of the multiple stacked bodies can be sensed.

The transmission line 51 is provided in the microwave sensors 122 and 123 recited above. The transmission line 51 includes the first conductive layer 51a.

The first conductive layer 51a includes a first region 51aA, a second region 51aB, and a third region 51aC. The direction from the first region 51aA toward the second region 51aB crosses the first direction D1. The direction from the first region 51aA toward the third region 51aC crosses the first direction D1.

The direction from the first region 51aA toward the first magnetic layer 21 is aligned with the first direction D1. The direction from the first region 51aA toward the second magnetic layer 22 is aligned with the first direction D1. The direction from the second region 51aB toward the third magnetic layer 23 is aligned with the first direction D1. The direction from the second region 51aB toward the fourth magnetic layer 24 is aligned with the first direction D1. The direction from the third region 51aC toward the fifth magnetic layer 25 is aligned with the first direction D1. The direction from the third region 51aC toward the sixth magnetic layer 26 is aligned with the first direction D1.

The antenna 61 and the amplifier 62 may be provided in microwave sensors 122 and 123.

### SEVENTH EMBODIMENT

The embodiment relates to a microwave imaging device.

FIG. 22 is a schematic view illustrating the microwave imaging device according to the seventh embodiment.

As shown in FIG. 22, the microwave imaging device 210 includes the microwave sensors and modifications of the microwave sensors according to the fifth and sixth embodiments. The microwave sensor 122 is provided in the example. The microwave sensor 122 includes the stacked body (the first stacked body 30A, etc.), the first controller 40A, etc. The microwave imaging device 210 may further include a microwave generator 71.

For example, the microwave 50 is irradiated on an object 70 (e.g., a measurement object) from the microwave generator 71. The microwave 50 is reflected by the object 70 and is incident on the microwave sensor 122.

For example, at least one of the angle between the microwave generator 71 and the object 70 or the angle between the microwave sensor 122 and the object 70 may be modified. For example, the microwave 50 may be scanned over the object 70.

Information that relates to the object 70 is obtained by sensing the microwave 50 reflected by the object 70. For example, information that relates to the object 70 in at least one of a Z1-direction (e.g., a depth direction), an X1-direction (e.g., a horizontal direction), or a Y1-direction (e.g., a vertical direction) is obtained. An image that corresponds to the object 70 can be derived based on this information. For example, it is possible to image the object 70.

In this specification, the state of being electrically connected includes the state in which a first conductor and a second conductor contact each other. The state of being electrically connected includes the state in which a third conductor is provided on a current path between the first conductor and the second conductor, and a current flows in the current path. The state of being electrically connected includes the state in which a control element such as a switch or the like is provided on a current path between a first conductor and a second conductor, and a state in which a current flows in the current path is formable by an operation of the control element.

Embodiments can include following configurations (technical idea):
(Configuration 1) A microwave sensor, comprising:

a first stacked body including a first magnetic layer, a second magnetic layer, and a first nonmagnetic layer, the first nonmagnetic layer being provided between the first magnetic layer and the second magnetic layer; and

a first controller electrically connected to the first magnetic layer and the second magnetic layer, the first controller being configured to supply a current to the first stacked body and being configured to sense a value corresponding to a first electrical resistance between the first magnetic layer and the second magnetic layer,

a second magnetization of the second magnetic layer is aligned with a first direction from the first magnetic layer toward the second magnetic layer,

the value corresponding to the first electrical resistance changes according to a microwave.
(Configuration 2) The sensor according to claim 1, wherein the first magnetization of the first magnetic layer is aligned with the first direction in a state in which the microwave is not applied to the first stacked body.
(Configuration 3) The sensor according to claim 1 or 2, wherein the current is a direct current.
(Configuration 4) The sensor according to one of claims 1-3, wherein the first magnetic layer includes a perpendicular magnetization film.
(Configuration 5) The sensor according to one of claims 1-4, wherein

the first magnetic layer includes at least one selected from the group consisting of a CoFeB film and a CoPt-containing film,

the CoPt-containing film includes a Co film and a Ft film, and

a direction from the Co film toward the Pt film is aligned with the first direction.
(Configuration 6) The sensor according to one of claims 1-3, further comprising a first magnetic field generator,

a first magnetic field being generated from the first magnetic field generator and applied to the first stacked body,

the magnetic field being aligned with the first direction.
(Configuration 7) The sensor according to claim 6, further comprising a magnetic field controller controlling the first magnetic field generator,

the magnetic field controller changing at least one of an orientation or a magnitude of the first magnetic field.
(Configuration 8) The sensor according to claim 6 or 7, further comprising a second magnetic field generator,

a position in the first direction of the first stacked body being between a position in the first direction of the first magnetic field generator and a position in the first direction of the second magnetic field generator.
(Configuration 9) The sensor according to one of claims 1-3, further comprising a magnetic portion,

a direction from the magnetic portion toward the first magnetic layer being aligned with the first direction,

a magnetization of the magnetic portion being aligned with the first direction.
(Configuration 10) The sensor according to one of claims 6-9, wherein the first magnetic layer includes an in-plane magnetization film.
(Configuration 11) The sensor according to one of claims 6-9, wherein the first magnetic layer includes at least one selected from the group consisting of Fe, Co, and Ni.
(Configuration 12) The sensor according to one of claims 1-11, wherein

the second magnetic layer includes at least one selected from the group consisting of a first structure, a second structure, and a third structure,

the first structure includes a Co film and a Pt film, a direction from the Co film toward the Pt film being aligned with the first direction,

the second structure includes a Co film and a Pd film, a direction from the Co film toward the Pd film being aligned with the first direction, and

the third structure includes a first magnetic film, a second magnetic film, and a Ru film provided between the first magnetic film and the second magnetic film, a direction from the first magnetic film toward the second magnetic film being aligned with the first direction.
(Configuration 13) The sensor according to one of claims 1-12, wherein the first controller includes a voltmeter.
(Configuration 14) The sensor according to one of claims 1-13, further comprising a transmission line including a first conductive layer,

a direction from the first conductive layer toward the first magnetic layer being aligned with the first direction,

a direction from the first conductive layer toward the second magnetic layer being aligned with the first direction.
(Configuration 15) The sensor according to claim 14, wherein

the transmission line further includes a second conductive layer and a third conductive layer, and

the first conductive layer is positioned between the second conductive layer and the third conductive layer in a direction crossing the first direction.
(Configuration 16) The sensor according to claim 14 or 15, further comprising:

an antenna; and

an amplifier amplifying a signal generated by the antenna,

an output portion of the amplifier being electrically connected to the first conductive layer.
(Configuration 17) The sensor according to one of claims 1-13, further comprising:

a second stacked body; and

a second controller,

the second stacked body including a third magnetic layer, a fourth magnetic layer, and a second nonmagnetic layer provided between the third magnetic layer and the fourth magnetic layer,

the second controller being electrically connected to the third magnetic layer and the fourth magnetic layer, being configured to supply a current to the second stacked body, and being configured to sense a value corresponding to a second electrical resistance between the third magnetic layer and the fourth magnetic layer,

a direction from the third magnetic layer toward the fourth magnetic layer being aligned with the first direction,

a fourth magnetization of the fourth magnetic layer being aligned with the first direction,

the value corresponding to the second electrical resistance changing according to the microwave,

a first resonance frequency of the first stacked body being different from a second resonance frequency of the second stacked body.
(Configuration 18) The sensor according to one of claims 1-13, further comprising a second stacked body,

the second stacked body including a third magnetic layer, a fourth magnetic layer, and a second nonmagnetic layer provided between the third magnetic layer and the fourth magnetic layer,

the first controller being electrically connected to the third magnetic layer and the fourth magnetic layer, being configured to further supply a current to the second stacked body, and being configured to further sense a value corresponding to a second electrical resistance between the third magnetic layer and the fourth magnetic layer,

a direction from the third magnetic layer toward the fourth magnetic layer being aligned with the first direction,

a fourth magnetization of the fourth magnetic layer being aligned with the first direction,

the value corresponding to the second electrical resistance changing according to the microwave,

a first resonance frequency of the first stacked body being different from a second resonance frequency of the second stacked body.
(Configuration 19) The sensor according to claim 17 or 18, further comprising a transmission line including a first conductive layer,

the first conductive layer including a first region and a second region,

a direction from the first region toward the second region crossing the first direction,

a direction from the first region toward the first magnetic layer being aligned with the first direction,

a direction from the first region toward the second magnetic layer being aligned with the first direction,

a direction from the second region toward the third magnetic layer being aligned with the first direction,

a direction from the second region toward the fourth magnetic layer being aligned with the first direction.
(Configuration 20) The sensor according to claim 19, further comprising:

an antenna; and

an amplifier amplifying a signal generated by the antenna,

an output portion of the amplifier being electrically connected to the first conductive layer.
(Configuration 21) A microwave imaging device including the microwave sensor according to one of claims 1 to 20.

According to the embodiments, a microwave sensor and a microwave imaging device can be provided in which the sensing sensitivity can be improved.

Hereinabove, embodiments of the invention are described with reference to specific examples. However, the invention is not limited to these specific examples. For example, one skilled in the art may similarly practice the invention by appropriately selecting specific configurations of components included in the microwave sensor or the microwave imaging device such as the stacked body, the magnetic layer, the nonmagnetic layer, the magnetic portion, the conductive layer, the transmission line, the interconnect, the current supply circuit, the sense circuit, etc., from known art; and such practice is within the scope of the invention to the extent that similar effects can be obtained.

Any two or more components of the specific examples may be combined within the extent of technical feasibility and are within the scope of the invention to the extent that the spirit of the invention is included.

All of microwave sensors and microwave imaging devices practicable by an appropriate design modification by one skilled in the art based on the microwave sensors and the microwave imaging devices described above as embodiments of the invention also are within the scope of the invention to the extent that the spirit of the invention is included.

Various modifications and alterations within the spirit of the invention will be readily apparent to those skilled in the art; and all such modifications and alterations should be seen as being within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A microwave sensor, comprising:
a first stacked body including a first magnetic layer, a second magnetic layer, and a first nonmagnetic layer, the first nonmagnetic layer being provided between the first magnetic layer and the second magnetic layer; and
a first controller electrically connected to the first magnetic layer and the second magnetic layer, the first controller being configured to supply a current to the first stacked body and being configured to sense a value corresponding to a first electrical resistance between the first magnetic layer and the second magnetic layer,
a second magnetization of the second magnetic layer is aligned with a first direction from the first magnetic layer toward the second magnetic layer,
the value corresponding to the first electrical resistance changes according to a microwave.

2. The sensor according to claim 1, wherein the first magnetization of the first magnetic layer is aligned with the first direction in a state in which the microwave is not applied to the first stacked body.

3. The sensor according to claim 1, wherein the current is a direct current.

4. The sensor according to claim 1, wherein the first magnetic layer includes a perpendicular magnetization film.

5. The sensor according to claim 1, wherein
the first magnetic layer includes at least one selected from the group consisting of a CoFeB film and a CoPt-containing film,
the CoPt-containing film includes a Co film and a Pt film, and
a direction from the Co film toward the Pt film is aligned with the first direction.

6. The sensor according to claim 1, further comprising a first magnetic field generator,
a first magnetic field being generated from the first magnetic field generator and applied to the first stacked body,
the magnetic field being aligned with the first direction.

7. The sensor according to claim 6, further comprising a magnetic field controller controlling the first magnetic field generator,
the magnetic field controller changing at least one of an orientation or a magnitude of the first magnetic field.

8. The sensor according to claim 6, further comprising a second magnetic field generator,
a position in the first direction of the first stacked body being between a position in the first direction of the first magnetic field generator and a position in the first direction of the second magnetic field generator.

9. The sensor according to claim 1, further comprising a magnetic portion,
a direction from the magnetic portion toward the first magnetic layer being aligned with the first direction,
a magnetization of the magnetic portion being aligned with the first direction.

10. The sensor according to claim 6, wherein the first magnetic layer includes an in-plane magnetization film.

11. The sensor according to claim 6, wherein the first magnetic layer includes at least one selected from the group consisting of Fe, Co, and Ni.

12. The sensor according to claim 1, wherein
the second magnetic layer includes at least one selected from the group consisting of a first structure, a second structure, and a third structure,
the first structure includes a Co film and a Pt film, a direction from the Co film toward the Pt film being aligned with the first direction,
the second structure includes a Co film and a Pd film, a direction from the Co film toward the Pd film being aligned with the first direction, and
the third structure includes a first magnetic film, a second magnetic film, and a Ru film provided between the first magnetic film and the second magnetic film, a direction from the first magnetic film toward the second magnetic film being aligned with the first direction.

13. The sensor according to claim 1, further comprising a transmission line including a first conductive layer,
a direction from the first conductive layer toward the first magnetic layer being aligned with the first direction,
a direction from the first conductive layer toward the second magnetic layer being aligned with the first direction.

14. The sensor according to claim 13, wherein
the transmission line further includes a second conductive layer and a third conductive layer, and
the first conductive layer is positioned between the second conductive layer and the third conductive layer in a direction crossing the first direction.

15. The sensor according to claim 13, further comprising:
an antenna; and
an amplifier amplifying a signal generated by the antenna,
an output portion of the amplifier being electrically connected to the first conductive layer.

16. The sensor according to claim 1, further comprising:
a second stacked body; and
a second controller,
the second stacked body including a third magnetic layer, a fourth magnetic layer, and a second nonmagnetic layer provided between the third magnetic layer and the fourth magnetic layer,
the second controller being electrically connected to the third magnetic layer and the fourth magnetic layer, being configured to supply a current to the second stacked body, and being configured to sense a value corresponding to a second electrical resistance between the third magnetic layer and the fourth magnetic layer,
a direction from the third magnetic layer toward the fourth magnetic layer being aligned with the first direction,
a fourth magnetization of the fourth magnetic layer being aligned with the first direction,
the value corresponding to the second electrical resistance changing according to the microwave,
a first resonance frequency of the first stacked body being different from a second resonance frequency of the second stacked body.

17. The sensor according to claim 1, further comprising a second stacked body,
the second stacked body including a third magnetic layer, a fourth magnetic layer, and a second nonmagnetic layer provided between the third magnetic layer and the fourth magnetic layer,
the first controller being electrically connected to the third magnetic layer and the fourth magnetic layer, being configured to further supply a current to the second stacked body, and being configured to further sense a value corresponding to a second electrical resistance between the third magnetic layer and the fourth magnetic layer,
a direction from the third magnetic layer toward the fourth magnetic layer being aligned with the first direction,
a fourth magnetization of the fourth magnetic layer being aligned with the first direction,
the value corresponding to the second electrical resistance changing according to the microwave,
a first resonance frequency of the first stacked body being different from a second resonance frequency of the second stacked body.

18. The sensor according to claim 16, further comprising a transmission line including a first conductive layer,
the first conductive layer including a first region and a second region,
a direction from the first region toward the second region crossing the first direction,
a direction from the first region toward the first magnetic layer being aligned with the first direction,
a direction from the first region toward the second magnetic layer being aligned with the first direction,
a direction from the second region toward the third magnetic layer being aligned with the first direction,
a direction from the second region toward the fourth magnetic layer being aligned with the first direction.

19. The sensor according to claim 18, further comprising:
an antenna; and
an amplifier amplifying a signal generated by the antenna,
an output portion of the amplifier being electrically connected to the first conductive layer.

20. A microwave imaging device including the microwave sensor according to claim 1.
